(19) United States
(12) Patent Application Publication
(10) Pub. No.: US 2026/0129883 A1
(43) Pub. Date: May 7, 2026

(54) RESISTOR STRUCTURE AND MANUFACTURING METHOD THEREOF

(71) Applicant: TAIWAN SEMICONDUCTOR MANUFACTURING COMPANY LTD., HSINCHU (TW)

(72) Inventors: PING-HSIANG HUANG, TAICHUNG CITY (TW); YOU-SHIUN CHOU, NEW TAIPEI CITY (TW); CHU FU CHEN, HSINCHU COUNTY (TW)

(21) Appl. No.: 18/938,318

(22) Filed: Nov. 6, 2024

(51) Int. Cl. H01L 23/522

(52) U.S. Cl. CPC H10D 1/476; H10W 20/498

(57) ABSTRACT

A resistor structure is provided. The resistor structure includes a substrate, a first well region formed in the substrate, a poly layer over the first well region, an isolation structure disposed between the poly layer and the first well region, and an interconnect structure. The poly layer has a first end, a second end and a point between the first and second ends. The interconnect structure is electrically connected between the point of the poly layer and the first well region.

### BACKGROUND

Resistor is a passive device most basic in analog circuit and/or a mixed-signal system. With the evolution of technique, the resistor is evolved to a polysilicon (poly) resistor in an integrated circuit. Resistance does not change with the voltage change for being added in its both ends or temperature in some applications requiring high accuracy or high stability, such as analog-to-digital converter (ADC), digital-to-analog converter (DAC), voltage regulator or voltage converter. The resistance drift of poly resistor will cause the distortion of output signal of circuits, greatly affecting the performance of the applications.

### BRIEF DESCRIPTION OF THE DRAWINGS

Aspects of the present disclosure are best understood from the following detailed description when read with the accompanying figures. It should be noted that, in accordance with standard practice in the industry, various features are not drawn to scale. In fact, the dimensions of the various features may be arbitrarily increased or reduced for clarity of discussion.

FIGS. 1A and 1B illustrate a semiconductor structure and an equivalent circuit (or a symbol) of a poly resistor, respectively, in accordance with some embodiments of the disclosure.

FIG. 2 illustrates a semiconductor structure of a poly resistor applied with an external bias voltage for biasing the N-type well region.

FIG. 3 illustrates the relationship between various electric fields and resistance drifts.

FIGS. 4A and 4B illustrate a semiconductor structure and an equivalent circuit (or a symbol) of a poly resistor, respectively, in accordance with some embodiments of the disclosure.

FIG. 5 illustrates a circuit diagram of a buck converter, in accordance with some embodiments of the disclosure.

FIG. 6 illustrates a circuit diagram of a boost converter, in accordance with some embodiments of the disclosure.

FIGS. 7A and 7B illustrate a semiconductor structure and an equivalent circuit of a resistor string, respectively, in accordance with some embodiments of the disclosure.

FIGS. 8A and 8B illustrate a semiconductor structure and an equivalent circuit of a resistor string, respectively, in accordance with some embodiments of the disclosure.

FIG. 9 illustrates a semiconductor structure of a resistor string, in accordance with some embodiments of the disclosure.

FIG. 10 illustrates a circuit diagram of a voltage divider, in accordance with some embodiments of the disclosure.

FIG. 11 illustrates a circuit diagram of a low-dropout regulator (LDO), in accordance with some embodiments of the disclosure.

FIG. 12 is a flowchart illustrating a method for manufacturing a resistor structure, in accordance with some embodiments of the disclosure.

### DETAILED DESCRIPTION

The following disclosure provides many different embodiments, or examples, for implementing different features of the provided subject matter. Specific examples of components and arrangements are described to simplify the disclosure. These are, of course, merely examples and are not intended to be limiting. For example, the formation of a first feature over or on a second feature in the description that follows may include embodiments in which the first and second features are formed in direct contact, and may also include embodiments in which additional features may be formed therebetween. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper,” “lower,” “left,” “right” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. It should be understood that when an element is referred to as being “connected to” or “coupled to” another element, it may be directly connected to or coupled to the other element, or intervening elements may be present.

As used herein, although the terms such as “first,” “second” and “third” describe various elements, components, regions, layers and/or sections, these elements, components, regions, layers and/or sections should not be limited by these terms. These terms may be only used to distinguish one element, component, region, layer or section from another. The terms such as “first,” “second” and “third” when used herein do not imply a sequence or order unless clearly indicated by the context.

Various poly resistor structures in integrated circuits (ICs) are provided in accordance with various exemplary embodiments. Some variations of embodiments are discussed. Throughout the various views and illustrative embodiments, like reference numbers are used to designate like elements.

Polysilicon (poly) resistors are characterized by their sheet resistance values. In order to reduce the chip size, the poly resistors with high sheet resistance values are often used and fabricated in a small area, and they are extensively used in a variety of integrated circuits. However, the depletion effect is a phenomenon in polysilicon, leading to unpredictable behavior of the poly resistors, such as non-linearity and resistance drift. For example, the poly resistor is formed on the well region of the semiconductor structure, and when a voltage is applied to the well region, it causes a depletion region to form in the polysilicon, which changes the effective resistance in the polysilicon layer.

According to the embodiments of the disclosure, a poly resistor includes a polysilicon (poly) layer, a well region and an isolation structure between the poly layer and the well region. The poly resistor further includes an interconnect structure configured to connect a midpoint of the poly layer to the well region, so as to provide a bias voltage to bias the well region according to the voltages at the opposite ends of the poly layer. By using the bias voltage generated from the poly layer to bias the well region, the electric field between the poly layer and the well region becomes more balanced and smaller, thereby preventing from resistance drift of the poly resistor.

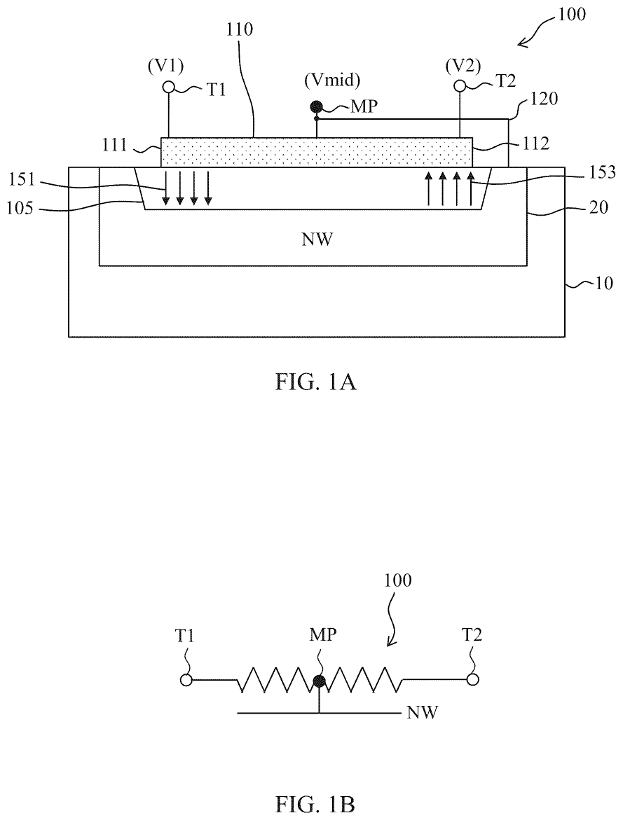

FIGS. 1A and 1B illustrate a semiconductor structure and an equivalent circuit (or a symbol) of a poly resistor 100, respectively, in accordance with some embodiments of the disclosure. The poly resistor 100 is formed over a substrate 10. The poly resistor 100 includes an N-type well (NW) region 20 in the substrate 10, an isolation structure 105 in the N-type well region 20, and a polysilicon (poly) layer 110 over the isolation structure 105.

The substrate 10 may include a semiconductor wafer such as a silicon wafer. Alternatively, the substrate 10 may include other elementary semiconductors such as germanium. The substrate 10 may also include a compound semiconductor such as silicon carbide, gallium arsenic, indium arsenide, and indium phosphide. The substrate 10 may include an alloy semiconductor such as silicon germanium, silicon germanium carbide, gallium arsenic phosphide, and gallium indium phosphide. In one embodiment, the substrate 10 includes an epitaxial layer (epi layer) overlying a bulk semiconductor. Furthermore, the substrate 10 may include a semiconductor-on-insulator (SOI) structure. For example, the substrate 10 may include a buried oxide (BOX) layer formed by a process such as separation by implanted oxygen (SIMOX). In some embodiments, the substrate 10 may include a buried layer such as an n-type buried layer (NBL), a p-type buried layer (PBL), and/or a buried dielectric layer including a buried oxide (BOX) layer.

The isolation structure 105 may be a shallow trench isolation (STI) or local oxidation of silicon (LOCOS). The isolation structure 105 is configured to prevent leakage between the poly layer 110 and the N-type well region 20. The N-type well region 20 may be a portion of the substrate 10, and may formed by various ion implantation processes. Top surfaces of the N-type well region 20 and the isolation structure 105 are at the same level. Alternatively, the N-type well region 20 may be portions of an epitaxy layer such as a silicon epitaxy layer formed by epitaxy processing. The N-type well region 20 may have an N-type dopant such as phosphorus. In some embodiments, the N-type doping material of the N-type well region 20 includes, for example, but is not limited to, phosphorus, arsenic, nitrogen, antimony, or combinations thereof. Other suitable doping materials are within the contemplated scope of the present disclosure. In some embodiments, the isolation structure 105 includes one or more layers of insulating materials, for example, silicon dioxide, silicon oxynitride and/or silicon nitride formed by LPCVD (low pressure chemical vapor deposition), plasma-enhanced (PE) CVD or flowable CVD.

The poly resistor 100 has a first terminal T1 and a second terminal T2. The poly layer 110 has a first end 111 and a second end 112, which are located apart from each other. The first terminal T1 is electrically connected to the first end 111 of the poly layer 110, and the second terminal T2 is electrically connected to the second end 112 of the poly layer 110. The poly layer 110 has a midpoint MP between the first end 111 and the second end 112. In other words, a length (or distance) between the first end 111 and the midpoint MP is equal to a length (or distance) between the second end 112 and the midpoint MP in the poly layer 110. In some embodiments, the poly layer 110 may have the serpentine layout with rectangular turns or circular turns. In some embodiments, the poly layer 110 may be formed from any known resistor material, such as metal, metal oxide and so on. For a given resistor material, the size of a resistor material line can be configured to arrive at resistors of different resistances.

The poly resistor 100 is connected to other devices of the circuit through the first terminal T1 and the second terminal T2. The midpoint MP is connected to the N-type well region 20 through an interconnect structure 120 formed by the metal lines (not shown) and the vias (not shown) over the substrate 10. The midpoint MP is configured to provide a bias voltage Vmid to bias the N-type well region 20. It should be noted that the midpoint MP is not connected to other devices of the circuit.

In the poly resistor 100, the bias voltage Vmid of the midpoint MP is provided according to a first voltage V1 at the first terminal T1 and a second voltage V2 at the second terminal T2. In some embodiments, a voltage difference between the first voltage V1 and the second voltage V2 is greater than 5V, |V1−V2|>5. Furthermore, the bias voltage Vmid is between the first voltage V1 and the second voltage V2, e.g., V2≤Vmid≤V1. If the first voltage V1 is greater than the second voltage V2, the bias voltage Vmid is equal to half the sum of the first voltage V1 and the second voltage V2, i.e., Vmid=(V1+V2)/2. For example, a voltage difference between the bias voltage Vmid and the first voltage V1 is equal to a voltage difference between the bias voltage Vmid and the second voltage V2, i.e., V1−Vmid=Vmid−V2. The first voltage V1 of the first terminal T1 is greater than the bias voltage Vmid of the midpoint MP, and an electric field 151 from the first end 111 of the poly layer 110 with the first voltage V1 to the N-type well region 20 with the bias voltage Vmid is present. Similarly, the bias voltage Vmid of the midpoint MP is greater than the second voltage V2 of the second terminal T2, and an electric field 153 from the N-type well region 20 with the bias voltage Vmid to the second end 112 of the poly layer 110 with the second voltage V2 is present.

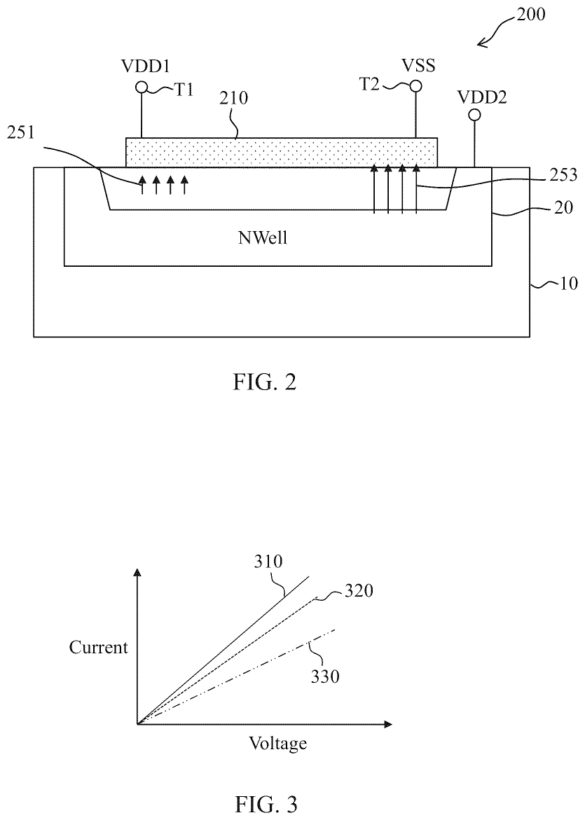

FIG. 2 illustrates a semiconductor structure of a poly resistor 200 with an external bias voltage VDD2 for biasing the N-type well region 20, i.e., the N-type well region 20 is tied to the external bias voltage VDD2. The external bias voltage VDD2 is provided by other device of the circuit, and the external bias voltage VDD2 may be independent of the voltages at the opposite terminals T1 and T2 of the poly resistor 200, and the voltage differences from the external bias voltage VDD2 to the voltages at the opposite terminals are different. For example, a voltage difference between the power supply voltage VDD1 and the external bias voltage VDD2 is less than a voltage different between the external bias voltage VDD2 and the ground voltage VSS. Thus, an electric field 251 from the N-type well region 20 to a portion of the poly layer 210 close to the first terminal T1 is less than an electric field 253 from the N-type well region 20 to a portion of the poly layer 210 close to the second terminal T2, i.e., the electric fields 251 and 253 are unbalanced.

Compared with the poly resistor 200 over the N-type well region 20 biased by the external bias voltage VDD2 in FIG. 2, the bias voltage Vmid is related to and between the first voltage V1 and the second voltage V2 in the poly resistor 100 of FIG. 1A. Therefore, the electric fields 151 and 153 of the poly resistor 100 are relatively balance and small, thereby preventing from resistance drift of the poly resistor 100. Furthermore, the N-type well region 20 is biased by the poly resistor 100 itself without the external bias voltage, thereby decreasing design complexity and cost and decreasing internal cross (e.g., coupling) over the delta voltage between the poly resistor 100 and other features in a semiconductor structure, e.g., from the poly resistor 100 to the active region, or the poly resistor 100 to the contact or metal line.

FIG. 3 illustrates the relationship between various electric fields and a resistance drift. In FIG. 3, the curve 310 represents the resistance of a poly resistor without an electric field. The curve 320 represents the resistance of the poly resistor 100 in FIG. 1 with balance electric fields, and the curve 330 represents the resistance of the poly resistor 200 of FIG. 2 with unbalance electric fields. The curve 320 is closer to the curve 310 than the curve 330, and the poly resistor 100 of FIG. 1A has the smaller resistance drift than the poly resistor 200 of FIG. 2.

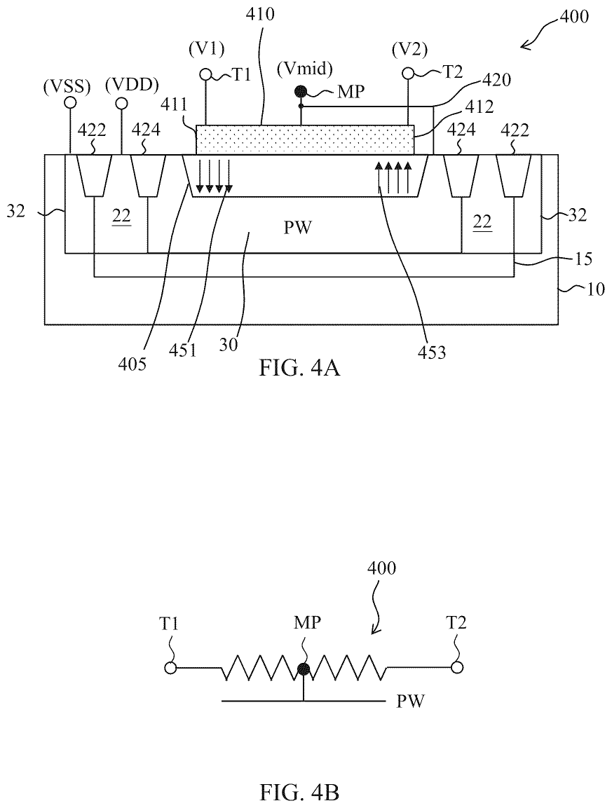

FIGS. 4A and 4B illustrate a semiconductor structure and an equivalent circuit (or a symbol) of a poly resistor 400, respectively, in accordance with some embodiments of the disclosure. The poly resistor 400 is formed over a substrate 10. The poly resistor 400 includes an N-type buried layer 15 in the substrate 10, a P-type well (PW) region 30, an isolation structure 405, a poly layer 410, an N-type well region 22, and a P-type well region 32.

The P-type well region 30 and the N-type well region 22 are separated from the substrate 10 by the N-type buried layer 15. In some embodiments, the N-type buried layer 15 may be a deep N-type well region. In some embodiments, the N-type well region 22 forms a ring, and the P-type well region 30 is completely surrounded by the N-type well region 22 from a top view, i.e., the N-type well region 22 laterally surrounds the P-type well region 30. In some embodiments, the P-type well region 32 forms a ring, and the N-type well region 22 is completely surrounded by the P-type well region 32 from a top view, i.e., the P-type well region 32 laterally surrounds the N-type well region 22. In some embodiments, the P-type well region 32 is omitted when the substrate 10 is a P-type substrate.

Each of the isolation structures 405, 422 and 424 may be a shallow trench isolation (STI) or local oxidation of silicon (LOCOS). The isolation structure 424 is disposed between the N-type well region 22 and the P-type well region 30, and the isolation structure 422 is disposed between the N-type well region 22 and the P-type well region 32. In some embodiments, the isolation structure 424 forms a ring, and the isolation structure 405 is completely surrounded by the isolation structure 424 from a top view. Furthermore, the isolation structure 422 forms a ring, and the isolation structure 424 is completely surrounded by the isolation structure 422 from a top view.

The N-type buried layer 15, the N-type well region 22 and the P-type well regions 30 and 32 may be a portion of the substrate 10, and may be formed by various ion implantation processes. Top surfaces of the N-type well region 22, the P-type well regions 30 and 32 and the isolation structures 405, 422 and 424 are at the same level. Furthermore, bottom surfaces of the N-type well region 22 and the P-type well regions 30 and 32 are at a first level, and bottom surfaces of the isolation structures 405, 422 and 424 are at a second level that is different from the first level. In some embodiments, the bottom surfaces of the isolation structures 422 and 424 and the bottom surfaces of the N-type well region 22 and the P-type well regions 30 and 32 are at the same level. In some embodiments, the thickness of the isolation structures 405, 422 and 424 is less than the N-type well region 20 and the P-type well regions 30 and 32. For example, the bottom surfaces of the isolation structures 405, 422 and 424 are closer to the poly layer 410 than the bottom surfaces of the N-type well region 20 and the P-type well regions 30 and 32.

Alternatively, the well regions 22, 30 and 32 may be portions of an epitaxy layer such as a silicon epitaxy layer formed by epitaxy processing. The N-type well region 22 may have an N-type dopant such as phosphorus, and the P-type well region 30 and 32 may have a P-type dopant such as boron. In some embodiment, the well regions 22, 30 and 32 may be formed by a plurality of processing steps, whether now known or to be developed, such as growing a sacrificial oxide on substrate, opening a pattern for the location(s) of the P-type well regions or N-type well regions, and implanting the impurities.

The poly resistor 400 has a first terminal T1 and a second terminal T2. In some embodiments, the first terminal T1 and the second terminal T2 are formed by electrodes and/or connection features. The poly layer 410 has a first end 411 and a second end 412, which are located apart from each other. The first terminal T1 is connected to the first end 411 of the poly layer 410, and the second terminal T2 is connected to the second end 412 of the poly layer 410. The poly layer 410 has a midpoint MP between the first end 411 and the second end 412. In other words, a length (or distance) between the first end 411 and the midpoint MP is equal to a length (or distance) between the second end 412 and the midpoint MP in the poly layer 410. In some embodiments, the poly layer 410 may have the serpentine layout with rectangular turns or circular turns.

The poly resistor 400 is connected to other devices of the circuit through the first terminal T1 and the second terminal T2. The midpoint MP is connected to the P-type well region 30 through an interconnect structure 420 formed by the metal lines (not shown) and the vias (not shown) over the substrate 10. The midpoint MP is configured to provide a bias voltage Vmid to bias the P-type well region 30. It should be noted that the midpoint MP is not connected to other devices of the circuit.

The power supply voltage VDD is applied to the N-type well region 22, and the ground voltage VSS is applied to the P-type well region 32. Thus, the N-type well region 22 is biased to a higher voltage than the P-type well region 32, thereby avoiding leakage from the P-type well region 32 to the N-type well region 22. Furthermore, the N-type buried layer 15 is biased by the power supply voltage VDD through the N-type well region 20. The P-type well region 30 is electrically separated from the substrate 10 by the N-type buried layer 15. Thus, the bias voltage Vmid of the P-type well region 30 is independent to the bias voltage (e.g., the ground voltage VSS) of the substrate 10. Furthermore, the bias voltage Vmid is less than the power supply voltage VDD, thereby avoiding leakage from the P-type well region 30 to the N-type well region 22.

In the poly resistor 400, the bias voltage Vmid of the midpoint MP is provided according to a first voltage V1 at the first terminal T1 and a second voltage V2 at the second terminal T2. In some embodiments, a voltage difference between the first voltage V1 and the second voltage V2 is greater than 5V, |V1−V2|>5. Furthermore, the bias voltage Vmid is between the first voltage V1 and the second voltage V2, e.g., V2≤Vmid≤V1. If the first voltage V1 is greater than the second voltage V2, the bias voltage Vmid is equal to half the sum of the first voltage V1 and the second voltage V2, i.e., Vmid=(V1+V2)/2. For example, a voltage difference between the bias voltage Vmid and the first voltage V1 is equal to a voltage difference between the bias voltage Vmid and the second voltage V2, i.e., V1−Vmid=Vmid−V2. The first voltage V1 of the first terminal T1 is greater than the bias voltage Vmid of the midpoint MP, and an electric field 451 from the first end 411 of the poly layer 410 to the P-type well region 30 is present. Similarly, the bias voltage Vmid of the midpoint MP is greater than the second voltage V2 of the second terminal T2, and an electric field 453 from the P-type well region 30 to the second end 412 of the poly layer 410 is present.

In the poly resistor over the P-type well region biased by the external bias voltage (e.g., the ground voltage VSS), the external bias voltage may be independent of the voltages at the opposite terminals of the poly resistor, and the voltage differences from the external bias voltage to the voltages at the opposite terminals are different. Compared with the poly resistor over the P-type well region biased by the external bias voltage, the bias voltage Vmid is related to and between the first voltage V1 and the second voltage V2 in the poly resistor 400 of FIG. 4A. Therefore, the electric fields 451 and 453 of the poly resistor 400 are relatively balanced and small, thereby preventing the resistance drift of the poly resistor 400. Furthermore, the P-type well region 30 is biased by the poly resistor 400 itself without the external bias voltage, thereby decreasing design complexity and cost and decreasing internal cross (e.g., coupling) over the delta voltage between the poly resistor 400 and other features in a semiconductor structure, e.g., from the poly resistor 400 to the active region, or the poly resistor 400 to the contact or metal line.

FIG. 5 illustrates a circuit diagram of a buck converter 500, in accordance with some embodiments of the disclosure. The buck converter 500 is capable of providing an output voltage Vout according to the power supply voltage VDD, and the power supply voltage VDD is greater than the output voltage Vout. In some embodiments, the output voltage Vout is greater than 5V. The buck converter 500 includes a voltage source 510, a transistor M1, an inductor L1, a diode D1, a capacitor C1 and a resistor R1. The voltage source 510 is configured to provide the power supply voltage VDD to the transistor M1. The transistor M1 is coupled between the voltage source 510 and the inductor L1, and the transistor M1 is a power switch controller by a control signal Ctrl1. The diode D1 is coupled between a first terminal of the inductor L1 and a ground VSS. The capacitor C1 is coupled between a second terminal of the inductor L2 and the ground VSS, and the capacitor C1 is connected in parallel with the resistor R1. In some embodiments, the resistor R1 is implemented by the poly resistor 100 of FIGS. 1A and 1B with the midpoint MP, and the midpoint MP is configured to provide the bias voltage Vmid to bias its N-type well region NW. In some embodiments, the resistor R1 is implemented by the poly resistor 400 of FIGS. 4A and 4B with the midpoint MP, and the midpoint MP is configured to provide the bias voltage Vmid to bias its P-type well region PW.

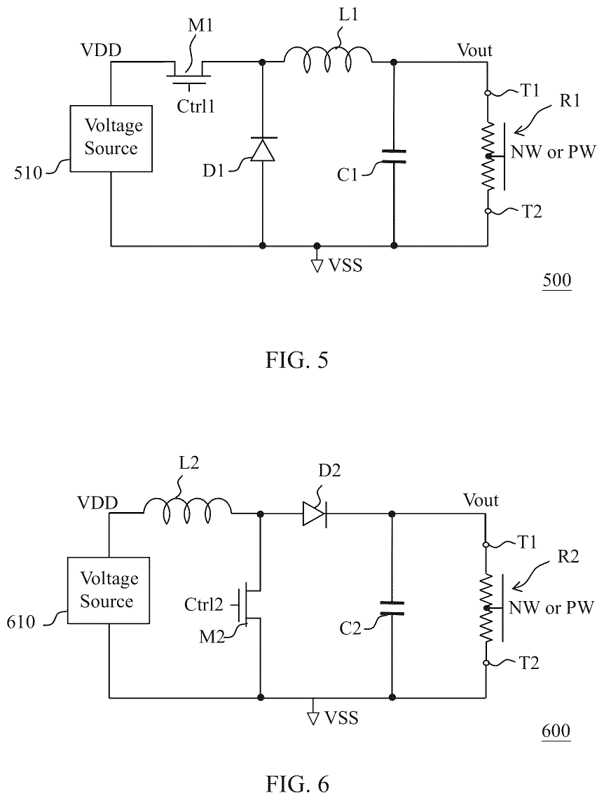

FIG. 6 illustrates a circuit diagram of a boost converter 600, in accordance with some embodiments of the disclosure. The boost converter 600 is capable of providing an output voltage Vout according to the power supply voltage VDD, and the power supply voltage VDD is less than the output voltage Vout. In some embodiments, the output voltage Vout is greater than 5V. The boost converter 600 includes a voltage source 610, a transistor M2, an inductor L2, a diode D2, a capacitor C2 and a resistor R2. The voltage source 610 is configured to provide the power supply voltage VDD to the inductor L2. The inductor L2 is coupled between the voltage source 610 and the anode of the diode D2. The transistor M2 is coupled between the anode of the diode D2 and the ground VSS, and the transistor M2 is a power switch controller by a control signal Ctrl2. The capacitor C2 is coupled between the cathode of the diode D2 and the ground VSS, and the capacitor C2 is connected in parallel with the resistor R2. In some embodiments, the resistor R2 is implemented by the poly resistor 100 of FIGS. 1A and 1B with the midpoint MP, and the midpoint MP is configured to provide the bias voltage Vmid to bias its N-type well region NW. In some embodiments, the resistor R2 is implemented by the poly resistor 400 of FIGS. 4A and 4B with the midpoint MP, and the midpoint MP is configured to provide the bias voltage Vmid to bias its P-type well region PW.

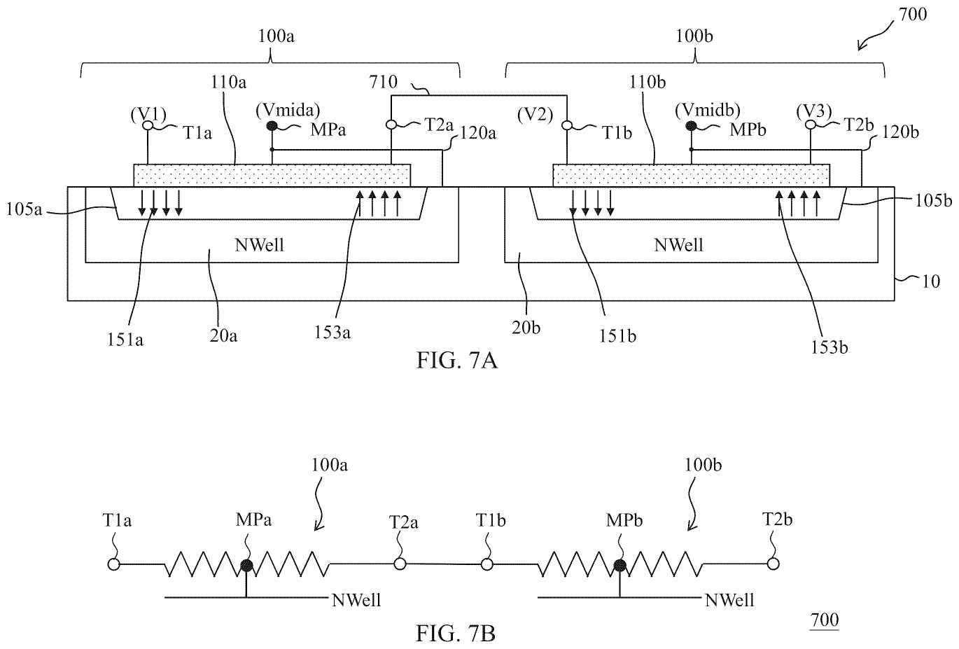

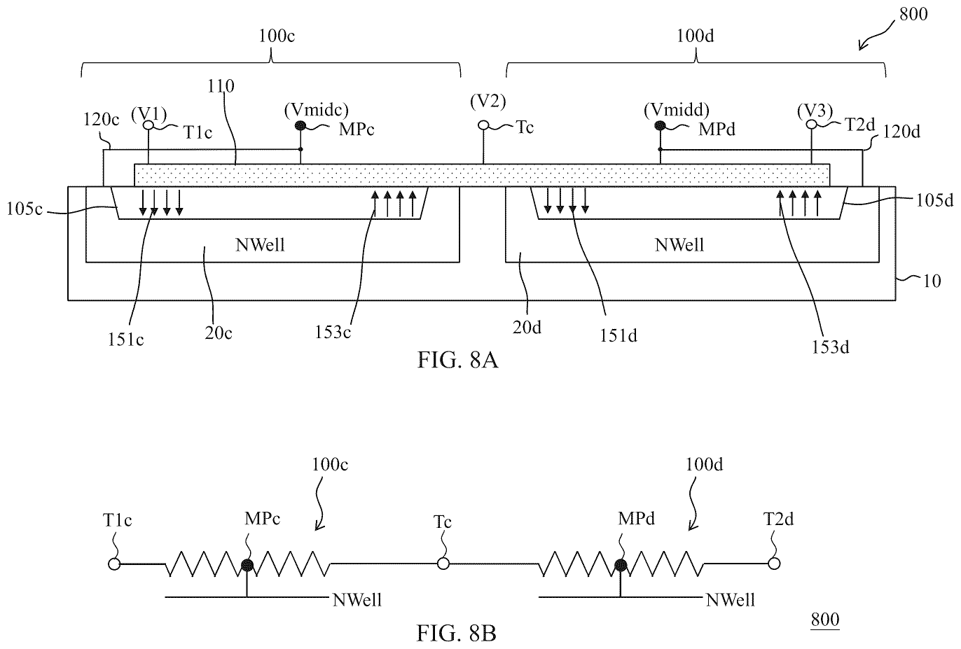

FIGS. 7A and 7B illustrate a semiconductor structure and an equivalent circuit of a resistor string 700, respectively, in accordance with some embodiments of the disclosure. The resistor string 700 is formed over a substrate 10. The resistor string 700 includes the poly resistors 100a and 100b connected in series. In the embodiment of the FIGS. 7A and 7B, the poly resistors 100a and 100b are implemented by the poly resistor 100 of FIGS. 1A and 1B. The N-type well region 20a of the poly resistor 100a is separated from the N-type well region 20b of the poly resistor 100b by the substrate 10. In some embodiments, the poly resistors 100a and 100b are implemented by the poly resistor 400 of FIGS. 4A and 4B. The resistor string 700 including two poly resistors 100a and 100b is used as an example, and not to limit the disclosure. The resistor string 700 may include more poly resistors connected in series according to various applications, such as voltage divider, low-dropout regulator (LDO), ADC, DAC, operation amplifier, bandgap circuit, AC to DC converter, DC to DC converter and so on. In some embodiments, some poly resistors are implemented by the poly resistor 400 with the P-type well region, and the remaining poly resistors are implemented by the poly resistor 100 with the N-type well region.

The poly resistor 100a includes the poly layer 110a over the isolation structure 105a, and is connected to other devices of the circuit through its first terminal T1a and its second terminal T2a, and the poly resistor 100b is connected to other devices of the circuit through its first terminal T2a and its second terminal T2b. The second terminal T2a of the poly resistor 100a is further connected to the first terminal T1b of the poly resistor 100b through an interconnect structure 710 formed by the metal lines (not shown) and the vias (not shown) over the substrate 10. The midpoint MPa of the poly resistor 100a is connected to its N-type well region 20a through the interconnect structure 120a, and the midpoint MPa is configured to provide a bias voltage Vmida to bias the N-type well region 20a. Similarly, the midpoint MPb of the poly resistor 100b is connected to its N-type well region 20b through the interconnect structure 120b, and the midpoint MPb is configured to provide a bias voltage Vmidb to bias the N-type well region 20b. It should be noted that the midpoints MPa and MPb are not connected to other devices of the circuit.

In the poly resistor 100a, the bias voltage Vmida at the midpoint MPa is provided according to a first voltage V1 at its first terminal T1a and a second voltage V2 at its second terminal T2a. In the poly resistor 100b, the bias voltage Vmidb at the midpoint MPb is provided according to the second voltage V2 at its first terminal T1b and a third voltage V3 at its second terminal T2b. In some embodiments, the poly resistors 100a and 100b have the same resistance. In some embodiments, the poly resistors 100a and 100b have different resistances. In some embodiments, a voltage difference between the first voltage V1 and the second voltage V2 and a voltage difference between the second voltage V2 and the third voltage V3 are greater than 5V, |V1−V2|>5 and |V2−V3|>5. In some embodiments, a voltage difference between the first voltage V1 and the third voltage V3 is greater than or equal to 5V, |V1−V3|>5. Furthermore, the bias voltage Vmida is between the first voltage V1 and the second voltage V2, e.g., V2≤Vmida≤V1, and the bias voltage Vmidb is between the second voltage V2 and the third voltage V3, e.g., V3≤Vmidb≤V2. In other words, the bias voltage Vmida is different from the bias voltage Vmidb.

When the first voltage V1 is greater than the third voltage V3 and the poly resistors 100a and 100b have the same resistance, the second voltage V2 is equal to half the sum of the first voltage V1 and the third voltage V3, i.e., V2=(V1+V3)/2. Furthermore, the bias voltage Vmida is equal to half the sum of the first voltage V1 and the second voltage V2, i.e., Vmida=(V1+V2)/2, and the bias voltage Vmidb is equal to half the sum of the second voltage V2 and third voltage V3, i.e., Vmidb=(V2+V3)/2. Therefore, a voltage difference between the bias voltage Vmida and the first voltage V1 is equal to a voltage difference between the bias voltage Vmida and the second voltage V2, i.e., V1−Vmida=Vmida−V2. Similarly, a voltage difference between the bias voltage Vmidb and the second voltage V2 is equal to a voltage difference between the bias voltage Vmidb and the third voltage V3, i.e., V2−Vmidb=Vmidb−V3. As described above, the electric fields 151a and 153a of the poly resistor 100a and the electric fields 151b and 153b of the poly resistor 100b are relatively balanced and small, thereby preventing a resistance drift of the resistor string 700.

FIGS. 8A and 8B illustrate a semiconductor structure and an equivalent circuit of a resistor string 800, respectively, in accordance with some embodiments of the disclosure. The resistor string 800 is formed over a substrate 10. The resistor string 800 includes the poly resistors 100c and 100d connected in series. In the embodiment of the FIGS. 8A and 8B, the configurations of the poly resistors 100c and 100d are similar with the configuration of the poly resistor 100 of FIGS. 1A and 1B. The N-type well region 20c of the poly resistor 100c is separated from the N-type well region 20d of the poly resistor 100d by the substrate 10. In some embodiments, the poly resistors 100c and 100d have the similar configuration of the poly resistor 400 of FIGS. 4A and 4B. The resistor string 800 including two poly resistors 100c and 100d is used as an example, and not to limit the disclosure. The resistor string 800 may include more poly resistors connected in series according to various applications, such as voltage divider, ADC, DAC and so on. In some embodiments, some poly resistors are implemented by the poly resistor 400 with the P-type well region, and the remaining poly resistors are implemented by the poly resistor 100 with the N-type well region.

In the resistor string 800, the poly layer 110 extends from the poly resistor 100c to the poly resistor 100d, and the second terminal T2 of the poly resistor 100c and the first terminal T1 of the poly resistor 100d are integrated as a common terminal Tc. For example, a second end (e.g., the second end 112 of FIG. 1) of the poly layer 110 of the poly resistor 100c extents to and contacts a first end (e.g., the first end 111 of FIG. 1) of the poly layer 110 of the poly resistor 100d. The poly resistor 100c is connected to other devices of the circuit through its first terminal T1c and the common terminal Tc, and the poly resistor 100d is connected to other devices of the circuit through its second terminal T2d and the common terminal Tc. In the embodiment, no interconnect structure (e.g., 710 of FIG. 7A) is used to connect the poly resistors 100c and 100d, thereby providing more area over the resistor string 800 for routing.

In some embodiments, the first terminal T1c and the second terminal T2d are disposed at opposite ends of the poly layer 110, and the command terminal Tc is disposed in the middle of the poly layer 110. In other words, a length (or distance) between the first terminal T1c and the common terminal Tc is equal to a length (or distance) between the second terminal T2d and the common terminal Tc in the poly layer 110.

The midpoint MPc of the poly resistor 100c is connected to its N-type well region 20c through the interconnect structure 120c, and the midpoint MPc is configured to provide a bias voltage Vmidc to bias the N-type well region 20c. Similarly, the midpoint MPd of the poly resistor 100d is connected to its N-type well region 20d through the interconnect structure 120d, and the midpoint MPd is configured to provide a bias voltage Vmidd to bias the N-type well region 20d. It should be noted that the middle terminals Tmidc and Tmidd are not connected to other devices of the circuit.

In the poly resistor 100c, the bias voltage Vmidc at the midpoint MPc is provided according to a first voltage V1 at its first terminal T1a and a second voltage V2 at the common terminal Tc. In the poly resistor 100d, the bias voltage Vmidd at the midpoint MPd is provided according to the second voltage V2 at the common terminal Tc and a third voltage V3 at its second terminal T2d. In some embodiments, the poly resistors 100c and 100d have the same resistance. In some embodiments, the poly resistors 100c and 100d have different resistances.

When the first voltage V1 is greater than the third voltage V3 and the poly resistors 100c and 100d have the same resistance, the second voltage V2 is equal to half the sum of the first voltage V1 and the third voltage V3, i.e., V2=(V1+V3)/2. Furthermore, the bias voltage Vmidc is equal to half the sum of the first voltage V1 and the second voltage V2, i.e., Vmida=(V1+V2)/2, and the bias voltage Vmidd is equal to half the sum of the second voltage V2 and third voltage V3, i.e., Vmidb=(V2+V3)/2. Therefore, a voltage difference between the bias voltage Vmidc and the first voltage V1 is equal to a voltage difference between the bias voltage Vmidc and the second voltage V2, i.e., V1−Vmidc=Vmidc−V2. Furthermore, a voltage difference between the bias voltage Vmidd and the second voltage V2 is equal to a voltage difference between the bias voltage Vmidd and the third voltage V3, i.e., V2−Vmidd=Vmidd−V3. As described above, the electric fields 151c and 153c of the poly resistor 100c and the electric fields 151d and 153d of the poly resistor 100d are relatively balanced and small, thereby preventing a resistance drift of the resistor string 800.

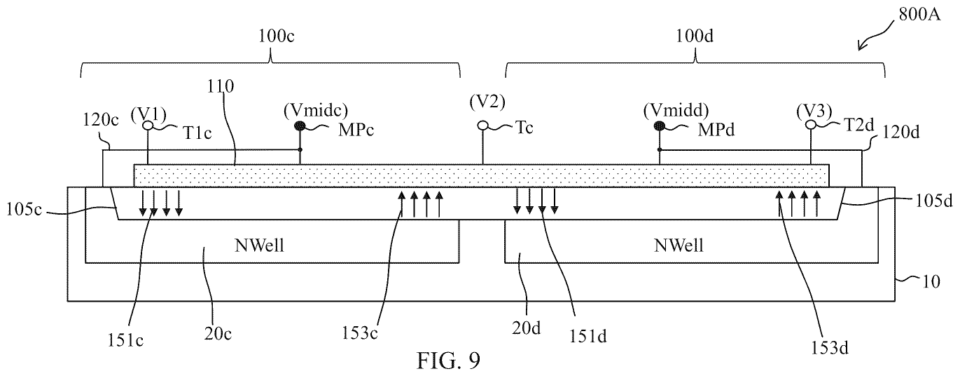

FIG. 9 illustrates a semiconductor structure of a resistor string 800A, respectively, in accordance with some embodiments of the disclosure. The configuration of the resistor string 800A of FIG. 9 is similar to the configuration of the resistor string 800 of FIG. 8A, and the difference is that the isolation structure 105 extends from the N-type well region 20c to the N-type well region 20d through the substrate 10 in the resistor string 800A of FIG. 9.

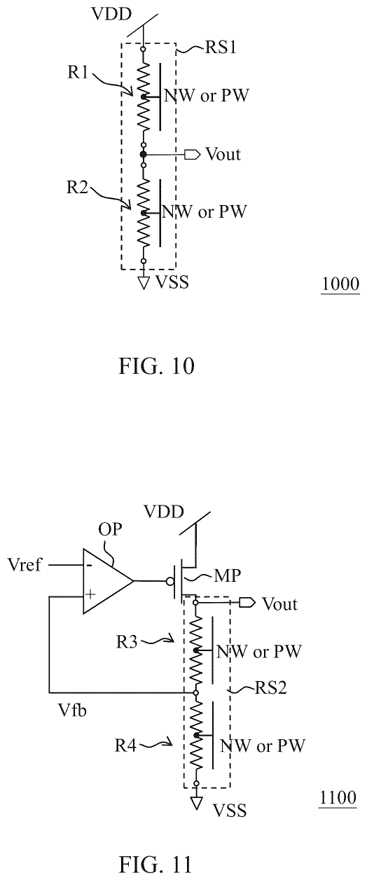

FIG. 10 illustrates a circuit diagram of a voltage divider 1000, in accordance with some embodiments of the disclosure. The voltage divider 1000 is capable of dividing the power supply voltage VDD to provide an output voltage Vout, and the output voltage Vout is greater than 5V. The voltage divider 1000 includes a resistor string RS connected between a power supply VDD and a ground VSS. The resistor string RS1 includes the resistors R1 and R2 connected in series. In the embodiment, the resistor string RS1 is implemented by the resistor string 700 of FIGS. 7A and 7B, and the resistors R1 and R2 are formed by the poly resistors 100a and 100b, respectively. The output voltage Vout is provided to the subsequent circuits through an interconnect structure between the resistors R1 and R2, such as the interconnect structure 710 of FIG. 7A.

FIG. 11 illustrates a circuit diagram of a LDO 1100, in accordance with some embodiments of the disclosure. The LDO 1100 is capable of providing an output voltage Vout according to a reference voltage Vref, and the output voltage Vout is greater than 5V. The LDO 1100 includes a resistor string RS2, a transistor MP and an operational amplifier OP. The transistor MP is connected between the power supply VDD and the resistor string RS2. The operational amplifier OP is configured to provide a signal to the gate of the transistor MP according to the reference voltage Vref and a feedback voltage Vfb from the resistor string RS2. The resistor string RS2 is connected between the transistor MP and the ground VSS, and the resistor string RS2 includes the resistors R3 and R4 connected in series. In the embodiment, the resistor string RS2 is implemented by the resistor string 800 of FIGS. 8A and 8B or the resistor string 800A of FIG. 9, and the resistors R3 and R4 are formed by the poly resistors 100c and 100d, respectively. The feedback voltage Vfb is provided to the operational amplifier OP through a common terminal between the resistors R3 and R4, such as the common terminal Tc of FIGS. 8A and 9.

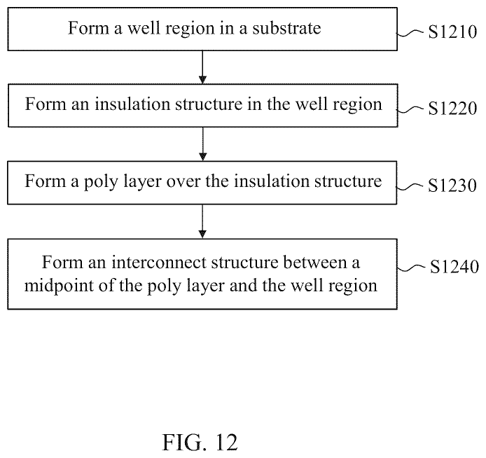

FIG. 12 is a flowchart illustrating a method for manufacturing a resistor structure, in accordance with some embodiments of the disclosure. It should be understood that the method shown in FIG. 12 is merely an example of many possible embodiments. One of ordinary skill in the art can recognize many variations, alternatives, and modifications. For example, various operations as illustrated in FIG. 12 can be added, removed, replaced, rearranged, or repeated.

In operation S1210, a well region (e.g., the N-type well region 20 of FIG. 1A or the P-type well region 30 of FIG. 4A) is formed in a substrate 10. In operation S1220, an isolation structure (e.g., the isolation structure 105 of FIG. 1A or the isolation structure 405 of FIG. 4A) is formed in the well region. In operation S1230, a poly layer (e.g., the poly layer 110 of FIG. 1A or the poly layer 410 of FIG. 4A) is formed over the isolation structure. In operation S1240, an interconnect structure (e.g., the interconnect structure 120 of FIG. 1A or the interconnect structure 420 of FIG. 4A) is formed between a midpoint MP of the poly layer and the well region.

In some embodiments, the well region and the substrate have the different conductive types, such as the poly resistor 100 of FIG. 1A. In some embodiments, the well region and the substrate have a first conductive type, and a deep well region formed between the well region and the substrate and another well region laterally surrounding the well region have a second conductive type, such as the poly resistor 400 of FIG. 4A.

According to some embodiments, a resistor structure is provided. The resistor structure includes a substrate, a first well region formed in the substrate, a poly layer over the first well region, an isolation structure disposed between the poly layer and the first well region, and an interconnect structure. The poly layer has a first end, a second end and a point between the first and second ends. The interconnect structure is electrically connected between the point of the poly layer and the first well region.

According to some embodiments, a resistor structure is provided. The resistor structure includes a substrate, and a resistor string over the substrate and including a plurality of poly resistors connected in series. Each of the poly resistors includes a first well region formed in the substrate, a poly layer over the first well region, an isolation structure disposed between the poly layer and the first well region, and an interconnect structure. The poly layer has a first end, a second end and a point between the first and second ends. The interconnect structure is configured to provide a bias voltage from the point of the poly layer to the first well region. The first well regions of the poly resistors are separated by the substrate.

According to some embodiments, a method for manufacturing a resistor structure is provided. The method includes forming a first well region in a substrate, forming an isolation structure in the first well region, forming a poly layer over the isolation structure, and forming an interconnect structure between a point of the poly payer and the first well region.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A resistor structure, comprising:
a substrate;
a first well region formed in the substrate;
a poly layer over the first well region, having a first end, a second end and a point between the first and second ends;
an isolation structure disposed between the poly layer and the first well region; and
an interconnect structure electrically connected between the point of the poly layer and the first well region.

2. The resistor structure of claim 1, wherein in the poly layer, a distance between the first end and the point is equal to a distance between the second end and the point.

3. The resistor structure of claim 1, wherein the substrate and the first well region have different conductive types.

4. The resistor structure of claim 1, further comprising:
a deep well region formed between the substrate and the first well region,
wherein the substrate and the first well region have a first conductive type, and the deep well region has a second conductive type.

5. The resistor structure of claim 4, further comprising:
a second well region laterally surrounding the first well region, and having the second conductive type,
wherein the substrate is separated from the first and second well regions by the deep well region.

6. The resistor structure of claim 1, wherein the interconnect structure is configured to provide a bias voltage from the point of the poly layer to bias the first well region.

7. The resistor structure of claim 6, wherein the bias voltage is equal to half the sum of a first voltage of the first end and a second voltage of the second end.

8. The resistor structure of claim 7, wherein a voltage difference between the first and second voltages is greater than 5V.

9. A resistor structure, comprising:
a substrate; and
a resistor string over the substrate and comprising a plurality of poly resistors connected in series,
wherein each of the poly resistors comprises:
a first well region formed in the substrate;
a poly layer over the first well region, having a first end, a second end and a point between the first and second ends;
an isolation structure disposed between the poly layer and the first well region; and
an interconnect structure configured to provide a bias voltage from the point of the poly layer to the first well region,
wherein the first well regions of the poly resistors are separated by the substrate.

10. The resistor structure of claim 9, wherein in the poly layer of each of the poly resistors, a distance between the first end and the point is equal to a distance between the second end and the point.

11. The resistor structure of claim 9, wherein the substrate and the first well regions of the poly resistors have different conductive types.

12. The resistor structure of claim 9, wherein the bias voltages provided to the first well regions of the poly resistors are different.

13. The resistor structure of claim 9, wherein each of the poly resistors further comprises:
a deep well region formed between the substrate and the first well region,
wherein the substrate and the first well region have a first conductive type, and the deep well region has a second conductive type.

14. The resistor structure of claim 13, wherein each of the poly resistors further comprises:
a second well region laterally surrounding the first well region, and having the second conductive type,
wherein the substrate is separated from the first and second well regions by the deep well region.

15. The resistor structure of claim 9, wherein in two adjacent poly resistors of the poly resistors, the second end of the poly layer of one poly resistor is coupled to the first end of the poly layer of the other poly resistor through another interconnect structure.

16. The resistor structure of claim 9, wherein in two adjacent poly resistors of the poly resistors, the second end of the poly layer of one poly resistor extends to and contact the first end of the other poly resistor.

17. A method for manufacturing a resistor structure, comprising:
forming a first well region in a substrate;
forming an isolation structure in the first well region;
forming a poly layer over the isolation structure; and
forming an interconnect structure between a point of the poly layer and the first well region.

18. The method of claim 17, wherein the poly layer has a first end and a second end, and a distance between the first end and the point is equal to a distance between the second end and the point.

19. The method of claim 17, wherein the substrate and the first well region have different conductive types.

20. The method of claim 17, further comprising:
forming a deep well region between the substrate and the first well region; and
forming a second well region to laterally surround the first well region,
wherein the substrate and the first well region have a first conductive type, and the deep well region and the second well region have a second conductive type,
wherein the substrate is separated from the first and second well regions by the deep well region.
